(19) United States
(12) Patent Application Publication
(10) Pub. No.: US 2025/0219548 A1
(43) Pub. Date: Jul. 3, 2025

(54) ELECTRIC POWER CONVERTER

(71) Applicant: Vacon Oy, Vaasa (FI)

(72) Inventors: Nicklas Södö, Vaasa (FI); Juha Norrena, Mustasaari (FI)

(21) Appl. No.: 18/989,803

(22) Filed: Dec. 20, 2024

(30) Foreign Application Priority Data
Dec. 28, 2023 (DE) 102023136766.8

(51) Int. Cl. H02M 7/00; H01F 27/24; H01F 27/28; H02M 7/04; H03H 7/01

(52) U.S. Cl. CPC H02M 7/003; H01F 27/24; H01F 27/28; H02M 7/043; H03H 7/0115

(57) ABSTRACT

An electric power converter, in particular for MVAC/LVAC to LVDC electric power conversion drives, including an active front end AFE, a transformer and an LCL-filter with a grid side choke and a drive side choke. According to the disclosure, the transformer and the LCL-filter are at least partially magnetically combined with each other.

### CROSS-REFERENCE TO RELATED APPLICATION

This application claims foreign priority benefits under 35 U.S.C. § 119 to German Patent Application No. 102023136766.8 filed on Dec. 28, 2023, the content of which is hereby incorporated by reference in its entirety.

### TECHNICAL FIELD

The present invention is directed at an electric power converter, in particular for MVAC/LVAC to LVDC electric power conversion drives. The converter comprises an active front end (AFE), a transformer and an LCL-filter with a grid side choke (L1) and a drive side choke (L2). According to the invention, the transformer and the LCL-filter are at least partially magnetically combined with each other.

### BACKGROUND

The invention relates to the optimization of LCL-filter and transformer application for MVAC/LVAC to LVDC conversion. MVAC or Medium Voltage AC electric power conversion drives typically operate in the range of above 1 Kilovolt and typically in a range of 3-4 Kilovolt, LVAC or Low Voltage AC electric power conversion drives typically operate in the range of below 1000 Volt AC and LVDC or Low Voltage DC electric power conversion drives typically operate in the range of below 1500 Volt DC.

Such power converters comprise transformer cores and other related components, which may use up a considerable amount of available space. Known converters require discrete components with corresponding higher space requirements, higher general complexity and more interfaces.

### SUMMARY

The aim of the present invention is to provide an improved electric power converter, which overcomes these problems. In particular, the presently described electric power converter offers the advantage of reduced total system complexity, cost and size.

This aim is achieved by an electric power converter according to claim 1. Preferable embodiments are subject to the dependent claims.

According to claim 1, an electric power converter is provided, preferably for MVAC/LVAC to LVDC electric power conversion drives. The electric power converter comprises an active front end, a transformer and an LCL-filter with a grid side choke and a drive side choke. According to the invention, the transformer and the LCL-filter are at least partially magnetically combined with each other. In particular, inductive components of the LCL-filter are at least partially magnetically combined with the transformer. The combination of the transformer and the LCL-filter or at least parts of the LCL-filter reduce the overall size of the electric power converter and the number of its components. The magnetic combination may relate to magnetic or magnetized components being shared between the transformer and the LCL-filter, such that the same magnetic component may, at the same time, be part of the transformer and the LCL-filter.

Thus, the basic idea of the present invention is to integrate filter components into the transformer, by partly using the same core for at least one of the inductors and the transformer or even using the stray inductance of the transformer as an inductor. By using the stray inductance of the transformer, it is possible to move some of the filter parts to the MV side or primary side of the transformer, where the current is much lower and thus less and cheaper material is needed for the respective components.

Overall, the presently described power converter provides simpler interfaces, is smaller, lighter, and less complex, than known solutions. It has better efficiency, while keeping the same robustness as converters known from the prior art. The reduced material requirements imply lower overall costs.

There are several ways, in which the combination of the various electric power converter components may be carried out. The following embodiments represent different degrees of integration of the electric power converter components.

In one preferred embodiment of the invention, a stray inductance of the transformer is used as part of the only grid side choke.

In another preferred embodiment of the invention, the magnetic flux in the grid side choke's core is closed by a part, in particular a top part of the transformer yoke.

In another preferred embodiment of the invention, at least one of the chokes and the transformer use the same core.

In another preferred embodiment of the invention, the grid side choke and the capacitor of the LCL-filter are provided on the primary side or higher voltage side of the transformer.

In another preferred embodiment of the invention, a circuit breaker is provided on the primary side of the transformer before or after the LC part filter. In this embodiment, the LCL-filter may be split into an LC part and an L part, or it may only comprise the LC part.

In another preferred embodiment of the invention, the drive side choke is provided on the secondary side of the transformer. Alternatively, the drive side choke could be provided on the primary side of the transformer.

In another preferred embodiment of the invention, the drive side choke and the secondary winding of the transformer share the same secondary winding.

### BRIEF DESCRIPTION OF THE DRAWINGS

Further details and advantages of the invention are described with reference to the embodiments shown in the figures. The figures show:

FIG. 1a: a schematic diagram of an electric power converter with Active Front End and LCL-filter;

FIG. 1b: a typical application of the electric power converter;

FIG. 2a: a perspective view of core sharing between a transformer and a choke;

FIG. 2b: an embodiment of the invention;

FIG. 3a: another embodiment of the invention; and

FIG. 3b: a perspective view of how windings can be provided for getting sufficient stray inductance between primary and secondary sides of the transformer.

### DETAILED DESCRIPTION

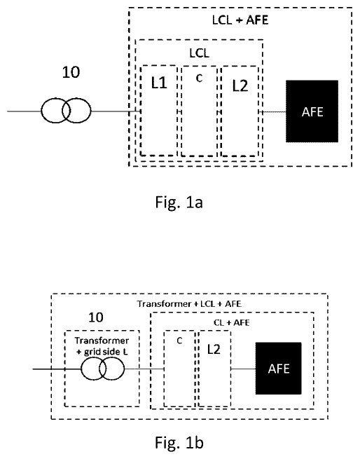

FIG. 1a is a schematic diagram of an electric power converter with an Active Front End AFE and an LCL-filter. The electric power converter is provided for e.g., MVAC/LVAC to LVDC electric power conversion drives. The electric power converter comprises an active front end AFE, a transformer 10 and an LCL-filter with a grid side choke L1 and a drive side choke L2.

The LCL-filter may be provided between the transformer 10 and the AFE. According to the invention, the transformer 10 and the LCL-filter are at least partially magnetically combined with each other. In particular, inductive components of the LCL-filter are at least partially magnetically combined with the transformer 10, i.e., they share some common magnetic components.

The combination of the transformer 10 and the LCL-filter or at least parts of the LCL-filter reduce the overall size of the electric power converter and the number of its components.

The combination of the transformer 10 and the LCL-filter makes it possible to use a stray inductance of the transformer 10 as part of the only grid side choke L1 of the LCL-filter.

FIG. 1b shows a typical application of the electric power converter. In this case, a dedicated transformer 10 is used with an AFE drive. The point of common coupling of the transformer 10 and the LCL filter is on the primary side of the transformer 10. The point of common coupling is a point, where the whole device including both, the filter and the transformer 10, is connected to grid and where other similar devices can also be connected. The term LCL-filter as presently used is understood in a broad sense, such that only the CL-part of the LCL-filter may actually be referred to.

The grid side choke L1 shown in FIG. 1a can be left out. Instead, only the natural stray inductance of the transformer 10 can be used as the corresponding inductance.

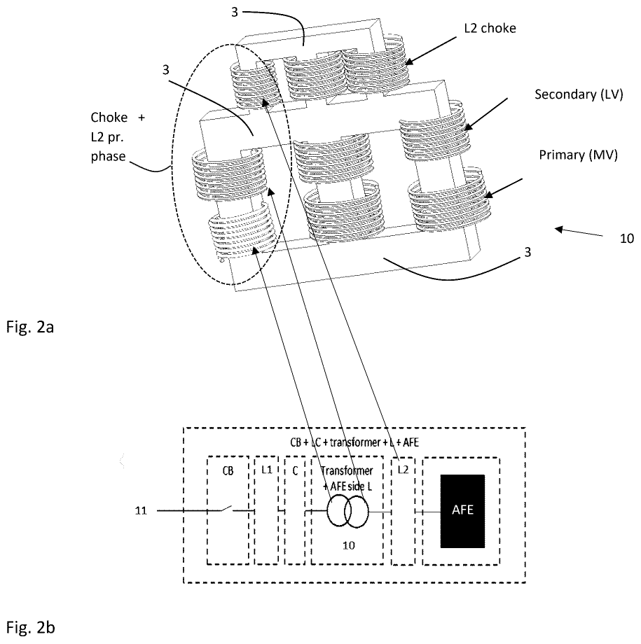

FIG. 2a shows a perspective view of core sharing between a transformer 10 and a choke. In this kind of setup, a drive side choke L2 can be mounted on top of the transformer 10 core, the drive side choke L2 having no own separate lower yoke. The magnetic flux in the drive side choke's L2 core is closed by the top part of the transformer 10 yoke.

It is possible to mount several chokes on top of the transformer 10, thus optimizing the needed amount of the core material. Any yoke can be shared between the transformer 10 and the chokes L1, L2.

Generally speaking, at least one of the chokes L1, L2 and the transformer 10 may use the same core or parts of the same core.

The transformer 10 may comprise three transformer yokes 3, between which the chokes L1, L2 may be arranged. The grid side choke L1 and the capacitor C may be separate components on the medium voltage MV side of the transformer 10.

FIG. 2b shows an embodiment of the invention, in which a circuit breaker CB is provided on the primary side of the transformer 10 before or after the LC part filter. The LCL-filter may be split such that its LC-part is situated between the transformer 10 and the grid 11 and its drive side choke L2 is provided between the transformer 10 and the AFE. In the shown embodiment, two drive side chokes L and L2 are provided. The circuit breaker CB may be provided between the LCL-filter and the grid 11.

The grid side choke L1 and the capacitor C of the LCL-filter are provided on the primary and higher voltage side of the transformer 10.

The main advantage of this embodiment is that components used in the LCL-filter can be split on both sides of the transformer 10, i.e., on the grid side and the AFE side of the transformer 10. The grid side choke L1 and the capacitor C may be provided on the primary side of the system, enabling major cost savings on system level design due to lower required current ratings. Also, the circuit breaker CB between the system and the grid 11 may be designed according to lower current ratings than needed on the secondary side of the transformer 10.

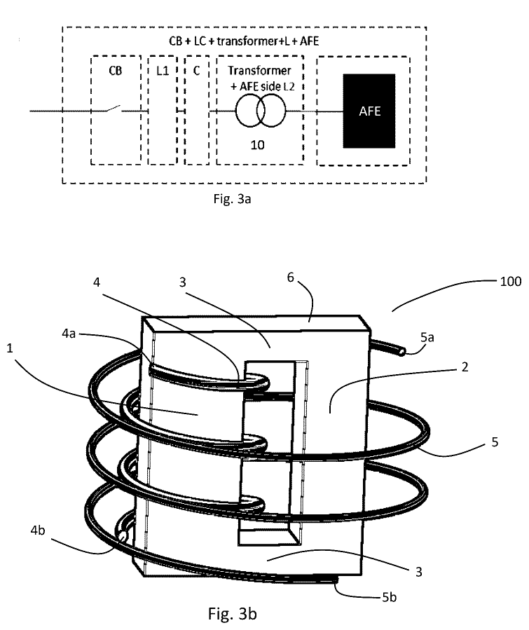

FIG. 3a shows another embodiment of the invention. Here, the transformer 10 is designed such that the drive side choke L2 or AFE side choke and the secondary winding of the transformer 10 share the same secondary winding. Thus, the drive side choke L2 may be provided on the secondary side of the transformer 10. There is no separate drive side choke L2 component as the transformer 10 stray inductance is dimensioned to the same inductance value as the drive side choke L2.

FIG. 3b is a simplified diagram on how windings can be provided for getting sufficient stray inductance between the primary and secondary sides of the transformer 10. The transformer 10 comprises two yokes 3 connected to the primary and secondary side 1, 2 of the transformer 10, forming the transformer core 6. The primary winding 4 of the grid side choke L1 is provided on the primary side 1 of the transformer 10, while the secondary winding 5 of the drive side choke L2 is provided around both, the primary and secondary side 1, 2 of the transformer 10. Primary And secondary winding ends 4a, 4b, 5a, 5b are indicated for better understanding. The transformer assembly 100 may comprise the transformer and any further components of the presently described electric power converter. The transformer assembly 100 introduces a method to integrate choke L2 into the transformer 10 without the need for any additional winding for choke L2. Instead, the core geometry is changed in order to increase the leakage inductance between the primary winding 4 and secondary winding 5.

While the present disclosure has been illustrated and described with respect to a particular embodiment thereof, it should be appreciated by those of ordinary skill in the art that various modifications to this disclosure may be made without departing from the spirit and scope of the present disclosure.

What is claimed is:

1. An electric power converter, in particular for MVAC/LVAC to LVDC electric power conversion drives, comprising an active front end (AFE), a transformer and an LCL-filter with a grid side choke (L1) and a drive side choke (L2), wherein the transformer and the LCL-filter are at least partially magnetically combined with each other.

2. The electric power converter according to claim 1, wherein a stray inductance of the transformer is used as part of the only grid side choke (L1).

3. The electric power converter according to claim 2, wherein the magnetic flux in the grid side choke's (L1) core is closed by a part of the transformer yoke.

4. The electric power converter according to claim 1, wherein at least one of the chokes (L1, L2) and the transformer use the same core.

5. The electric power converter according to claim 1, wherein the grid side choke (L1) and the capacitor (C) of the LCL-filter are provided on the primary side of the transformer.

6. The electric power converter according to claim 1, wherein a circuit breaker (CB) is provided on the primary side of the transformer before or after the LC part filter.

7. The electric power converter according to claim 1, wherein the drive side choke (L2) is provided on the secondary side of the transformer.

8. The electric power converter according to claim 7, wherein the drive side choke (L2) and the secondary winding of the transformer share the same secondary winding.

9. The electric power converter according to claim 2, wherein at least one of the chokes (L1, L2) and the transformer use the same core.

10. The electric power converter according to claim 3, wherein at least one of the chokes (L1, L2) and the transformer use the same core.

11. The electric power converter according to claim 2, wherein the grid side choke (L1) and the capacitor (C) of the LCL-filter are provided on the primary side of the transformer.

12. The electric power converter according to claim 3, wherein the grid side choke (L1) and the capacitor (C) of the LCL-filter are provided on the primary side of the transformer.

13. The electric power converter according to claim 4, wherein the grid side choke (L1) and the capacitor (C) of the LCL-filter are provided on the primary side of the transformer.

14. The electric power converter according to claim 2, wherein a circuit breaker (CB) is provided on the primary side of the transformer before or after the LC part filter.

15. The electric power converter according to claim 3, wherein a circuit breaker (CB) is provided on the primary side of the transformer before or after the LC part filter.

16. The electric power converter according to claim 4, wherein a circuit breaker (CB) is provided on the primary side of the transformer before or after the LC part filter.

17. The electric power converter according to claim 5, wherein a circuit breaker (CB) is provided on the primary side of the transformer before or after the LC part filter.
